(19) United States
(12) Patent Application Publication
(10) Pub. No.: US 2009/0065911 A1
(43) Pub. Date: Mar. 12, 2009

(54) SEMICONDUCTOR PACKAGE AND MANUFACTURING METHOD THEREOF

(75) Inventors: Chia-Fu Wu, Kaohsiung City (TW); Cheng-Yin Lee, Tainan City (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 12/208,881

(22) Filed: Sep. 11, 2008

(30) Foreign Application Priority Data
Sep. 12, 2007 (TW) 96134069

(51) Int. Cl. H01L 23/495; H01L 21/56; H01L 23/48

(52) U.S. Cl. 257/666; 438/123; 257/738; 438/127; 257/E23.031; 257/E21.502; 257/E23.023

(57) ABSTRACT

A semiconductor package includes a carrier, at least one chip, an encapsulation, and a patterned conductive film. The carrier has a first surface and a second surface opposite to the first surface. The chip is disposed on the first surface of the carrier and electrically connected to the carrier. The encapsulation encapsulates the chip and at least a portion of the first surface of the carrier. The patterned conductive film is disposed on the encapsulation to electrically connect to the carrier. A manufacturing method of the semiconductor package is also disclosed.

### CROSS-REFERENCE TO RELATED APPLICATION

This application claims the priority benefit of Taiwan application serial no. 96134069, filed on Sep. 12, 2007. The entirety of the above-mentioned patent application is hereby incorporated by reference herein and made a part of specification.

### BACKGROUND OF THE INVENTION

1. Field of the Invention

The present invention generally relates to a package and a manufacturing method thereof, in particular, to a semiconductor package and a manufacturing method thereof.

2. Description of Related Art

In the semiconductor technology development, the capacity and performance of semiconductor package devices are improved to meet the demands of users along with the miniaturization and high-efficiency oriented development of electronic products. Therefore, multi-chip module becomes one of the researching focuses in recent years, in which a semiconductor package is formed by stacking two or more chips. 20 However, as the volume of the stacked semiconductor package is increased, miniaturization also becomes an important topic. In addition, it is one of the researching directions how to prevent an electromagnetic interference (EMI) of the semiconductor package.

Referring to FIG. 1, a conventional semiconductor package 1 includes a carrier 11, a chip 12, and an encapsulation 13. The chip 12 is wire-bonded to the carrier 11, and the encapsulation 13 encapsulates the chip 12 and one side of the carrier 11. In order to prevent the EMI, the semiconductor package 1 further has a shielding body 14, which is disposed on periphery of the encapsulation 13 and is grounded. However, the shielding body 14 increases the production cost, and a bonding force between the shielding body 14 and the carrier 11 may be slowly weakened with the time, even the shielding body 14 may be separated from the carrier 11. In addition, the shielding body 14 also increases the volume of the semiconductor package 1, which is disadvantageous to the miniaturization.

In addition, other electronic devices may also be disposed on the semiconductor package 1 to become a stacking structure. For the stacking manner, for example, firstly a lead frame or a substrate is disposed on the encapsulation 13, and then one or more chips or packages are disposed on the lead frame. However, the lead frame cannot abut against the encapsulation 13 because of the structure limit (line width and thickness), and the stacking manner using the lead frame is not helpful to reduce the size of the semiconductor package.

Therefore, it becomes one of the important topics how to provide a semiconductor package and a manufacturing method thereof, capable of shortening a vertical stacking height, reducing the size of the semiconductor package, and preventing the EMI.

### SUMMARY OF THE INVENTION

Accordingly, the present invention is directed to a semiconductor package and a manufacturing method thereof, capable of effectively shortening a vertical stacking height, reducing a size, and preventing the EMI.

As embodied and broadly described herein, the present invention provides a semiconductor package, which includes a carrier, at least one chip, an encapsulation, and a patterned conductive film. The carrier has a first surface and a second surface opposite to the first surface. The chip is disposed on the first surface of the carrier, and is electrically connected to the carrier. The encapsulation encapsulates the chip and at least a portion of the first surface of the carrier. The patterned conductive film is disposed on the encapsulation, so as to electrically connect to the carrier.

The present invention provides a manufacturing method of a semiconductor package, which includes the following steps. Firstly, a package is provided. The package includes a carrier, at least one chip, and an encapsulation. The carrier has a first surface and a second surface opposite to the first surface. The chip is disposed on the first surface of the carrier, and is electrically connected to the carrier. The encapsulation encapsulates the chip and at least a portion of the first surface of the carrier. Then, a patterned conductive film is formed on the encapsulation, so as to electrically connect to the carrier.

In view of the above, in the semiconductor package and the manufacturing method thereof of the present invention, the patterned conductive film is directly formed on the encapsulation, and the patterned conductive film may be stacked with and electrically connected to other electronic devices, so as to form a stacked semiconductor package. In addition, a portion of the patterned conductive film may be grounded and has the function of preventing the EMI. As compared with the conventional art, the patterned conductive film of the present invention does not have the structure limit of the conventional lead frame, thus effectively shortening the vertical stacking height and reducing the size.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a conventional semiconductor package.

FIG. 2A is a schematic view of a semiconductor package according to an embodiment of the present invention.

FIG. 2B is a schematic view of the semiconductor package of FIG. 2A and a patterned conductive film thereof.

FIG. 3 is a flow chart of processes of a manufacturing method of the semiconductor package according to the embodiment of the present invention.

FIGS. 4A to 4B are schematic views of the manufacturing method of FIG. 3.

FIGS. 5 to 8 are schematic views of different alternative aspects of the semiconductor package according to the present invention externally connecting to the electronic devices.

FIGS. 9A and 9B are schematic views of the semiconductor package according to the present invention using a lead frame as a carrier.

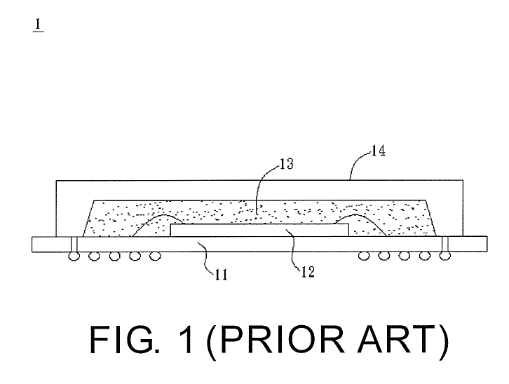

### DESCRIPTION OF THE EMBODIMENTS

In the following, referring to relative drawings, a semiconductor package and a manufacturing method thereof according to an embodiment of the present invention are described, in which the same elements are marked by the same reference numerals.

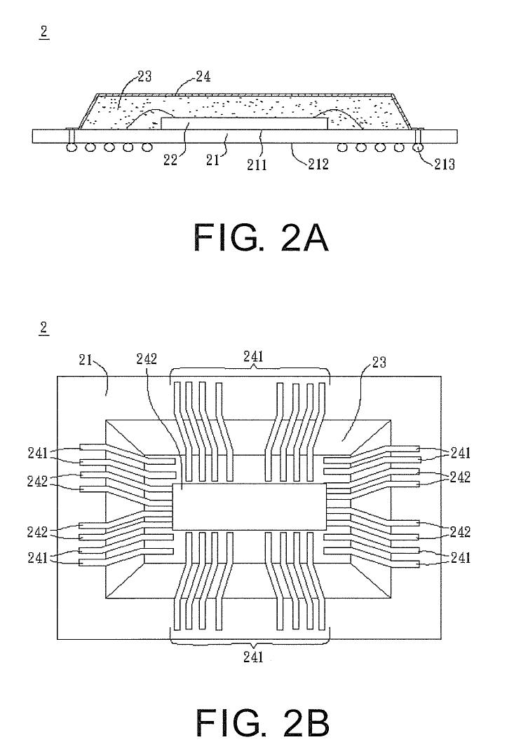

Referring to FIG. 2A, a semiconductor package 2 according to an embodiment of the present invention includes a carrier 21, at least one chip 22, an encapsulation 23, and a patterned conductive film 24.

The carrier 21 has a first surface 211 and a second surface 212 opposite to the first surface 211. The chip 22 is disposed on the first surface 211 of the carrier 21, and may be electrically connected to the carrier 21 through conductive bumps or bonding wires, and here for example the bonding wires are adopted. The second surface 212 of the carrier 21 has a plurality of solder balls 213, for electrically connecting to other electronic devices, for example, a circuit board (not shown). The encapsulation 23 encapsulates the chip 22 and at least a portion of first surface 211 of the carrier 21. The encapsulation 23 may be epoxy resin or silicone. The patterned conductive film 24 is disposed on the encapsulation 23 and may extend to the first surface 211, and is electrically connected to at least one of the solder balls 213 through a conductive via of the carrier 21.

Referring to FIGS. 2A and 2B together, the patterned conductive film 24 includes a wire pattern 241 and an electromagnetic restraining pattern 242. The wire pattern 241 is electrically connected to at least one of the ungrounded solder balls 213 of the second surface 212. The electromagnetic restraining pattern 242 is grounded by electrically connecting to the grounded solder balls 213 of the second surface 212, so as to provide an electromagnetic shielding function. The electromagnetic restraining pattern 242 is disposed on the position except for the wire pattern 241. Definitely, the electromagnetic restraining pattern 242 may be directly grounded without using the solder balls 213. In addition, the carrier 21 has a wire redistribution layer (not shown), and the wire pattern 241 and the electromagnetic restraining pattern 242 may be electrically connected to the corresponding solder balls 213 through the wire redistribution layer.

In this embodiment, the size and the shape of the wire pattern 241 and the electromagnetic restraining pattern 242 are not limited. The patterned conductive film 24 may be formed on any position of the encapsulation 23, and may extend to the first surface 211 of the carrier 21.

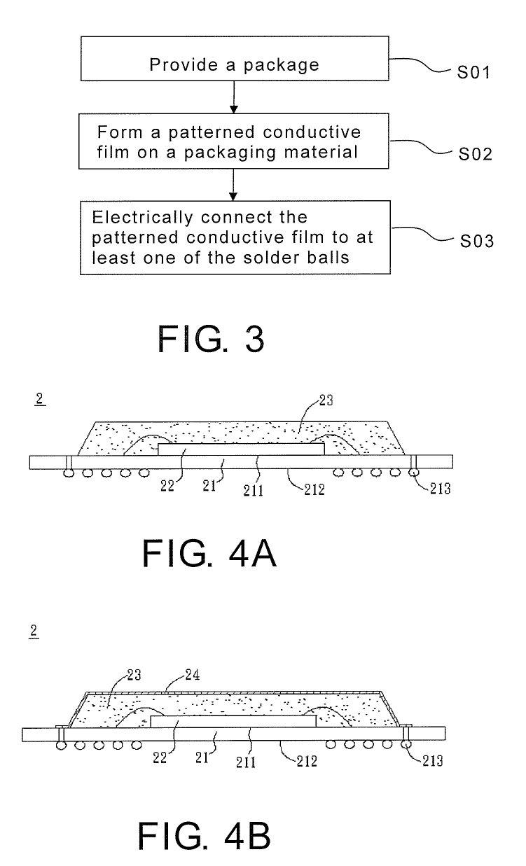

Referring to FIG. 3, a manufacturing method of the semiconductor package according to the embodiment of the present invention includes Step S01 to Step S03. Referring to FIGS. 3, 4A, and 4B together, the manufacturing method of the semiconductor package 2 is further described.

Referring to FIGS. 3 and 4A, in Step S01, a package is provided. The package includes a carrier 21, at least one chip 22, and an encapsulation 23. The implementing aspects of the carrier 21, the chip 22, and the encapsulation 23 are described above, and thus will not be repeated here.

Referring to FIGS. 3 and 4B, in Step S02, a patterned conductive film 24 is formed on the encapsulation 23. The patterned conductive film 24 may be formed on the encapsulation 23 by depositing, coating, printing, or electroplating. The depositing may be physical depositing, for example, sputtering. Before the patterned conductive film 24 is formed, the manufacturing method of this embodiment further includes forming an uneven structure or a roughened structure on an outer surface of the encapsulation 23, so as to enhance a bonding force between the patterned conductive film 24 and the encapsulation 23. The uneven structure is, for example, a combination of grooves and/or protrusions, and the roughened structure is, for example, a rough surface.

Then, in Step S03, the patterned conductive film 24 is electrically connected to at least one of the solder balls 213, and the patterned conductive film 24 is electrically connected to the solder balls 213 through the conductive via of the carrier 21. [0027] The manufacturing method of this embodiment further includes a step of stacking the patterned conductive film 24 with and electrically connecting the patterned conductive film 24 to at least one electronic device. Here, the type of the electronic device is not limited, for example, the electronic device may be selected from a group consisting of a chip, a package, a multi-chip module (MCM), a multi-package module (MPM), and a combination thereof. In the following, the different alternative aspects of the patterned conductive film 24 externally connecting to the electronic device are described.

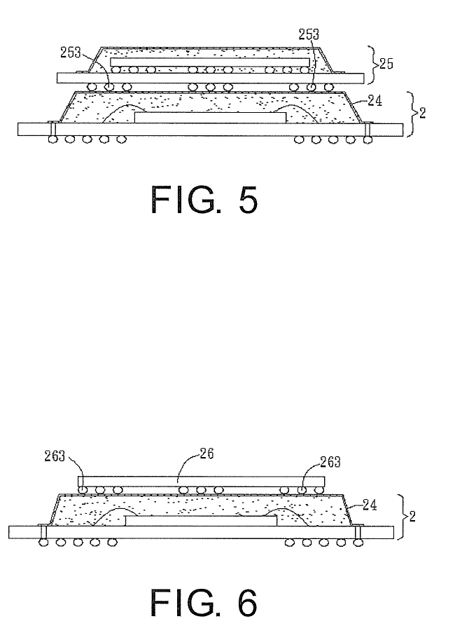

Referring to FIG. 5, a package 25 is disposed on the semiconductor package 2, and is stacked with and electrically connected to the patterned conductive film 24. A portion of the solder balls 253 of the package 25 may be electrically connected to the wire pattern 241 of the patterned conductive film 24, and the other portion of the solder balls 253 may be electrically connected to the electromagnetic restraining pattern 242 of the patterned conductive film 24. In addition, the semiconductor package 2 and the package 25 may be encapsulated by another encapsulation, so as to provide a protecting function.

Referring to FIG. 6, a chip 26 is, for example, disposed on the semiconductor package 2 through conductive bumps, and is stacked with and electrically connected to the patterned conductive film 24. A portion of conductive bumps 263 of the chip 26 may be electrically connected to the wire pattern 241 of the patterned conductive film 24, and the other portion of the conductive bumps 263 may be electrically connected to the electromagnetic restraining pattern 242 of the patterned conductive film 24. The manufacturing method further includes a step of encapsulating the chip 26 and the semiconductor package 2 by another encapsulation, for providing the protecting function.

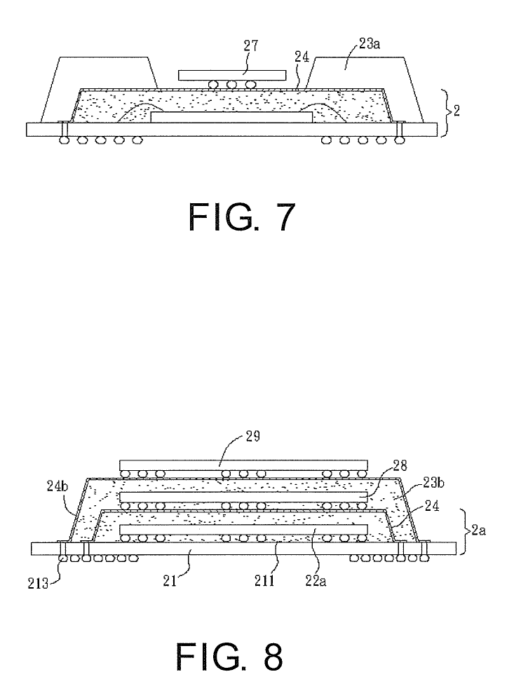

As shown in FIG. 7, a chip 27 is, for example, disposed on the semiconductor package 2 through the conductive bumps, and is electrically connected to the patterned conductive film 24. The manufacturing method further includes a step of encapsulating a portion of the semiconductor package 2 by another encapsulation 23a, and forming a cavity for placing the chip 27. The encapsulation 23a exposes a portion of the patterned conductive film 24 and forms a cavity, such that the exposed patterned conductive film 24 may be used to selectively stack with and electrically connect with various electronic devices, for example, the chip 27.

Referring to FIG. 8, a chip 22a of a semiconductor package 2a is disposed on the carrier 21 through the conductive bumps. A chip 28 is disposed on the semiconductor package 2a through the conductive bumps, and is electrically connected to the patterned conductive film 24. An encapsulation 23b encapsulates the chip 28 and the semiconductor package 2a. A patterned conductive film 24b is disposed on the encapsulation 23b, extends to the first surface 211 of the carrier 21, and is electrically connected to the solder ball 213.

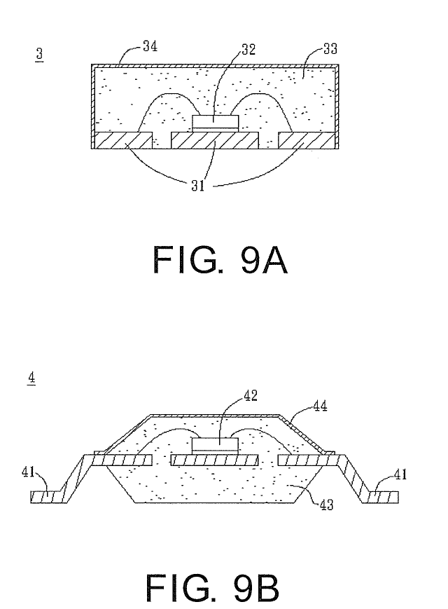

The carrier of the above embodiment is, for example, a circuit substrate, and in addition, the carrier of the present invention may be a lead frame. Referring to FIG. 9A, a semiconductor package 3 includes a lead frame 31, a chip 32, an encapsulation 33, and a patterned conductive film 34. The chip 32 is electrically connected to the lead frame 31 through the bonding wires. The encapsulation 33 encapsulates the chip 32 and a portion of the lead frame 31. The patterned conductive film 34 is disposed on the encapsulation 33 and is electrically connected to the lead frame 31. Here, the lead frame 31 is a quad flat non-leaded package (QFN) lead frame.

In addition, referring to FIG. 9B, a semiconductor package 4 includes a lead frame 41, a chip 42, an encapsulation 43, and a patterned conductive film 44. The chip 42 is electrically connected to the lead frame 41 through the bonding wires. The encapsulation 43 encapsulates the chip 32 and a portion of the lead frames 41. The patterned conductive film 44 is disposed on the encapsulation 43 and is electrically connected to the lead frame 41. Here, the lead frame 41 is a quad flat package (QFP) lead frame.

To sum up, in the semiconductor package and the manufacturing method thereof according to the present invention, the patterned conductive film is directly formed on the encapsulation, and the patterned conductive film may be stacked with and electrically connected to other electronic devices, so as to form a stacked semiconductor package. In addition, a portion of the patterned conductive film may be grounded and has the function of preventing the EMI. As compared with the prior art, the patterned conductive film of the present invention does not have the structure limit of the conventional lead frame, thus effectively shortening the vertical stacking height and reducing the size.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor package, comprising:
a carrier, having a first surface and a second surface opposite to the first surface;
at least one chip, disposed on the first surface of the carrier, and electrically connected to the carrier;
an encapsulation, encapsulating the chip and at least a portion of the first surface of the carrier; and
a patterned conductive film, disposed on the encapsulation, so as to electrically connect to the carrier.

2. The semiconductor package according to claim 1, wherein the second surface comprises a plurality of solder balls.

3. The semiconductor package according to claim 2, wherein the patterned conductive film comprises a wire pattern electrically connected to at least one of the solder balls.

4. The semiconductor package according to claim 2, wherein the patterned conductive film comprises an electromagnetic restraining pattern electrically connected to at least one of the solder balls.

5. The semiconductor package according to claim 1, wherein the patterned conductive film is stacked with and electrically connected to at least one electronic device, and the electronic device is selected from a group consisting of a chip, a package, a multi-chip module (MCM), a multi-package module (MPM), and a combination thereof.

6. The semiconductor package according to claim 5, wherein the semiconductor package and the electronic device are encapsulated by another encapsulation.

7. The semiconductor package according to claim 5, wherein another encapsulation encapsulates a portion of the semiconductor package, and forms a cavity for placing the electronic device.

8. The semiconductor package according to claim 1, wherein an outer surface of the encapsulation comprises an uneven structure or a roughened structure, for bonding to the patterned conductive film.

9. The semiconductor package according to claim 1, wherein the carrier is a circuit substrate or a lead frame, and the lead frame is a quad flat package (QFP) lead frame or a quad flat non-leaded package (QFN) lead frame.

10. A manufacturing method of a semiconductor package, comprising:
providing a package, wherein the package comprises a carrier, at least one chip, and an encapsulation, the carrier comprises a first surface and a second surface opposite to the first surface, the chip is disposed on the first surface of the carrier and electrically connected to the carrier, the encapsulation encapsulates the chip and at least a portion of the first surface of the carrier; and
forming a patterned conductive film on the encapsulation, so as to electrically connect to the carrier.

11. The manufacturing method according to claim 10, wherein the patterned conductive film is formed on the encapsulation by depositing, coating, printing, or electroplating.

12. The manufacturing method according to claim 10, wherein the second surface comprises a plurality of solder balls.

13. The manufacturing method according to claim 12, wherein the patterned conductive film comprises a wire pattern electrically connected to at least one of the solder balls.

14. The manufacturing method according to claim 12, wherein the patterned conductive film comprises an electromagnetic restraining pattern, electrically connected to at least one of the solder balls.

15. The manufacturing method according to claim 10, further comprising stacking the patterned conductive film with and electrically connecting the patterned conductive film to at least one electronic device, wherein the electronic device is selected from a group consisting of a chip, a package, a multi-chip module (MCM), a multi-package module (MPM), and a combination thereof.

16. The manufacturing method according to claim 15, further comprising encapsulating the semiconductor package and the electronic device by another encapsulation.

17. The manufacturing method according to claim 15, further comprising encapsulating a portion of the semiconductor package by another encapsulation, and forming a cavity for placing the electronic device.

18. The manufacturing method according to claim 10, before forming the patterned conductive film, further comprising:
forming an uneven structure or a roughened structure on an outer surface of the encapsulation, for bonding to the patterned conductive film.

19. The manufacturing method according to claim 10, wherein the carrier is a circuit substrate or a lead frame, and the lead frame is a quad flat package (QFP) lead frame or a quad flat non-leaded package (QFN) lead frame.
